(19) United States
(12) Patent Application Publication
(10) Pub. No.: US 2021/0166981 A1
(43) Pub. Date: Jun. 3, 2021

(54) METHOD AND DEVICE FOR REPAIRING AN INTERNAL CIRCUIT BREAK DEFECT IN A CHIP

(71) Applicant: GUANGDONG UNIVERSITY OF TECHNOLOGY, Guangzhou (CN)

(72) Inventors: Yun CHEN, Guangzhou (CN); Yao YAO, Guangzhou (CN); Shuquan DING, Guangzhou (CN); Junyu LONG, Guangzhou (CN); Maoxiang HOU, Guangzhou (CN); Dachuang SHI, Guangzhou (CN); Xin CHEN, Guangzhou (CN); Jian GAO, Guangzhou (CN); Qiang LIU, Guangzhou (CN); Lanyu ZHANG, Guangzhou (CN); Yunbo HE, Guangzhou (CN); Shenghui ZHANG, Guangzhou (CN); Zhengping WANG, Guangzhou (CN)

(21) Appl. No.: 17/037,849

(22) Filed: Sep. 30, 2020

(30) Foreign Application Priority Data
Nov. 29, 2019 (CN) 201911206961.7

(51) Int. Cl. H01L 21/66; B23K 26/08; B23K 26/06; B23K 26/082

(52) U.S. Cl. CPC H01L 22/22; B23K 26/0853; B23K 2101/40; B23K 26/0665; B23K 26/082; B23K 26/0608

(57) ABSTRACT

The disclosure relates to a method for repairing an internal circuit break defect in a chip, including: S1, detecting the defect position of the chip and the type and performance parameters of a filling material; S2, positioning the chip on a two-dimensional motion platform; S3, setting parameters of two beams of laser; adjusting a focal length of the two beams of laser three-dimensional incident angle and a Z axis, so that a focus point of the two beams of laser irradiate any end of the circuit break of the chip; S4, the two-dimensional motion platform drives the chip to move, so that the focus point of the two beams of laser is moved to an other end of the circuit break, and an moving trajectory of the focus point of the two beams of laser feeds through the two ends of the circuit break of the chip.

### CROSS-REFERENCE TO RELATED APPLICATIONS

This application claims the benefit of priority from Chinese Patent Application No. 201911206961.7, filed on Nov. 29, 2019. The content of the aforementioned applications, including any intervening amendments thereto, is incorporated herein by reference in its entirety.

### TECHNICAL FIELD

The disclosure relates to the technical field of chip repairing, in particular to a repairing method and device for an internal circuit break defect in a chip.

### BACKGROUND OF THE DISCLOSURE

A chip is a general name of a semiconductor integrated device, and a block of silicon wafer integrated with transistor circuits, undergoing mounting, interconnection, injection molding and other packaging steps, becoming into a chip capable of being used. The manufacturing complete process of a chip includes several steps, such as chip design, wafer manufacturing, packaging manufacturing, testing and the like, and performing test after each step is completed, so that unqualified products are screened out. The tube core circuit interconnection is the most important part of the chip package, and the semiconductor failure is about ¼ to ⅓ caused by the error of the interconnection circuit, so that repair and adjustment of a chip are of great significance to the reliability of the device.

For the chip with unqualified packaging test, the packaging material of the chip is generally stripped, and the defect of the interconnection circuit is checked for repairing. If an interconnection circuit short occurs, repair can be realized by laser ablation; however, for the condition of disconnection of the interconnection circuit, the repair method is relatively complex. The existing repairing means is printing a conductive circuit for repairing by adopting a 3D printing technology. For example, An international famous PCB 3D printer manufacturer launched in 2016, the world's first dedicated printing PCB desktop printer which can print more than ten layers of electronic circuits (containing inter-layer interconnection and through holes) in several hours.

However, in domestic, the research of electronic circuit 3D printer mostly stays in terms of theoretical research, forming the proto-printer, but a printer with product properties does not be produced; or the produced electronic circuit 3D printer is relatively low in precision and can lead to short circuit of adjacent lines. In addition, it is also extremely difficult to perform repair when removing the packaging material after being packaged.

Therefore, it is desirable to provide a method for repairing internal circuit defects in a chip which can be accurately controlled, simple to operate and high in repair rate.

### SUMMARY OF THE DISCLOSURE

The disclosure aims at overcoming the defects in the prior art, and provides a method and device for quickly repairing an internal circuit break defect in a chip.

In order to achieve the purpose, the disclosure adopts the following technical solutions:

A method for repairing an internal circuit break defect in a chip, comprising the following steps:

S1, performing industrial CT detection on the chip, and detecting the defect position of the chip and the type and performance parameters of a filling material;

S2, placing the chip on a two-dimensional motion platform, positioning the chip, calibrating an original point on the chip, and setting speed and displacement parameters of an X and Y axis of the two-dimensional motion platform;

S3, setting parameters of two beams of laser according to the performance parameters of the filling material, setting power, scanning speed and scanning frequency of the laser; adjusting a focal length of the two beams of laser three-dimensional incident angle and a Z axis, so that a focus point of the two beams of laser irradiate any end of the circuit break of the chip, and modifying the filling material at the end to be graphene;

S4, the two-dimensional motion platform drives the chip to move, so that the focus point of the two beams of laser is moved to an other end of the circuit break, and an moving trajectory of the focus point of the two beams of laser feeds through the two ends of the circuit break of the chip.

Further, adjusting a wavelength and frequency of the two beams of laser, so that the two beams of laser generate stable interference and cancellation at the focus points.

Further, a speed range of the X and the Y axis of the two-dimensional motion platform in the S2 is 1-10 mm/s.

Further, a wavelength range of the two beams of laser is 300 nm to 1064 nm.

Further, an incident angle range of the two beams of laser is 0-90° from the vertical direction, and an included angle between the two beams of laser is 30-150°.

Further, the focus point of the two beams of laser in the S4 feeds through the two ends of the circuit break of the chip in a three-dimensional motion trajectory.

A repair device for repairing an internal circuit break defect in a chip, comprising: a computer system, a three-dimensional scanning galvanometer, a laser device and a two-dimensional motion platform; the computer system is respectively connected with the three-dimensional scanning galvanometer and the two-dimensional motion platform; a defective chip is placed on the two-dimensional motion platform; the three-dimensional scanning galvanometer is arranged above the two-dimensional motion platform; and laser device emits two beams of laser, and the two beams of laser are focused on the circuit break position of the chip through the three-dimensional scanning galvanometer.

Further, the laser device has a power range of 150 W˜500 W, a wavelength range of 300 nm˜1064 nm, a scanning speed range of 0.5˜80 mm/s, an energy density range of 95-105 W/cm²; and a focal length of Z axis of the three-dimensional scanning galvanometer has an adjustable range of 10˜150 mm.

The disclosure has the beneficial effects that the laser beam penetrates through the chip packaging shell in a certain direction in the form of light energy, the energy exposure to the packaging shell is very dispersed and the packaging shell is only subjected to instantaneous irradiation, and therefore the packaging shell cannot be damaged. As long as the focus point is aligned to the break point of the circuit, and then scanning along a certain path to another break point, the organic filler on this path can be modified into graphene. Because the size of the chip is small, the size of the internal circuit reaches a micron level, and the common laser does not meet the precision requirement. The focal length of the Z axis of the three-dimensional scanning galvanometer is adjustable, coordinating with the movement of the two-dimensional platform, so that a large accumulation error does not occur in the whole repairing process. The disclosure is of the application of the laser-induced graphene technology in the field of chip repair. The device of the disclosure has the advantages of high precision, high repair rate, simple operation and the like.

### BRIEF DESCRIPTION OF THE DRAWINGS

The disclosure is further explained below in combination with the accompanying drawings and embodiments.

FIG. 1 is a schematic diagram of an internal structure of a chip according to an embodiment of the disclosure;

FIG. 2 is a schematic diagram of an embodiment of the disclosure;

FIG. 3 is an overall structural schematic diagram of an embodiment of the disclosure;

FIG. 4 is an overall structural schematic diagram of an embodiment of the disclosure;

FIG. 5 is a flow chart of an embodiment of the disclosure.

### REFERENCE OF THE DRAWINGS

wherein, a computer system 101, a three-dimensional scanning galvanometer 103, a laser device 103, a laser 104, a two-dimensional motion platform 105, a chip 106, a filling material 202, a wafer 203, a circuit break 204 and a bonding pad 205.

### DETAILED DESCRIPTION OF EMBODIMENTS

The technical solutions of the disclosure are further illustrated by the following detailed description in conjunction with the accompanying drawings.

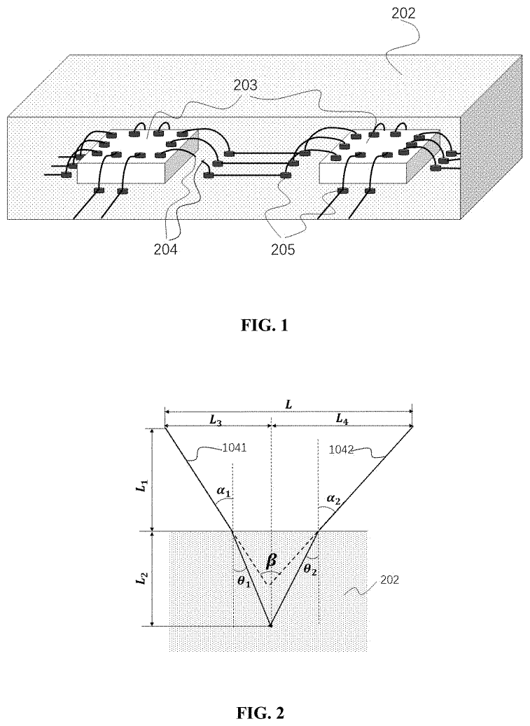

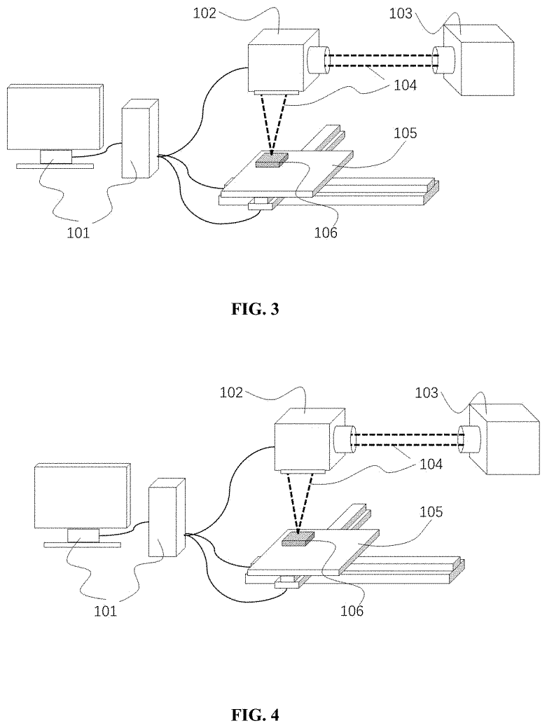

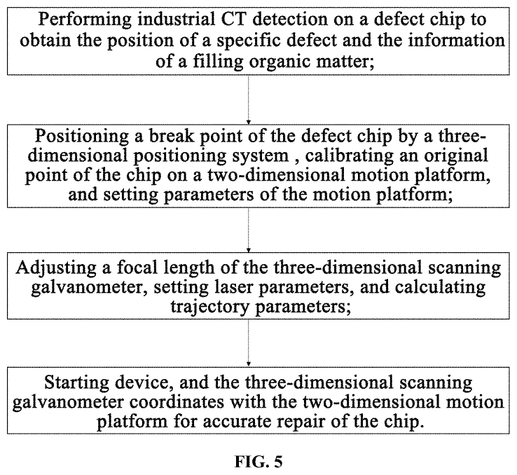

As shown in FIGS. 1-4, a method for repairing an internal circuit break defect in a chip 106 includes the following steps:

S1, performing industrial CT detection on the chip 106, and detecting the defect position of the chip 106 and the type and performance parameters 202 of a filling material;

S2, placing the chip 106 on a two-dimensional motion platform 105, positioning the chip 106, calibrating an original point on the chip 106, and setting speed and displacement parameters of an X and Y axis of the two-dimensional motion platform 105;

S3, setting parameters of two beams of laser 104 according to the performance parameters of the filling material 202, setting power, scanning speed and scanning frequency of the laser 104; adjusting a focal length of the two beams of laser 104 three-dimensional incident angle and a Z axis, so that a focus point of the two beams of laser 104 irradiate any end of the circuit break 204 of the chip 106, and modifying the filling material 202 at the end to be graphene;

S4, the two-dimensional motion platform 105 drives the chip 106 to move, so that the focus point of the two beams of laser 104 is moved to an other end of the circuit break 204, and an moving trajectory of the focus point of the two beams of laser feeds through the two ends of the circuit break 204 of the chip 106.

As shown in FIG. 1, when the chip 106 is packaged, after tube core circuits being interconnected, a wafer 203 is filled with molten organic matter, such as epoxy, anhydride, acrylate and the like, and the pins are led out for packaging, so that the wafer 203 and the surrounding tube core circuit are wrapped, physical and electrical protection is provided, and external interference is prevented. For the laser 104, the laser 104 has two properties of a photochemical effect and a thermal effect, and when the two beams of laser 104 are emitted into the organic matter from different angles, the lasers 104 accurately converge at a point, and a large amount of energy is released due to the interference and cancellation of the two beams of laser 104 on the focal point. The energy density of the laser 104 at a certain point is related to the size of its light spot at the point, and the larger the energy density generated by the same laser 104 beam, the smaller the light spot is. The energy density must be greater than a certain critical value to denature the filling organic matter, or called threshold value. By proper focusing, the energy density of the laser 104 can be lower than the threshold value of denaturing of the filling organic matter before entering the filling organic matter and reaching the processing area, and in the desired area of processing, the energy density of the laser 104 is above the critical value, the laser 104 generates a pulse in a very short time, so that the energy of the laser 104 can instantaneously enable the filling organic matter to be modified into graphene, so that a predetermined shape is scanned in the filling organic matter to form a conductive circuit, and the external packaging of the chip 106 is kept intact.

After the chip 106 is damaged during use, the device of the disclosure can be used for repair. The three-dimensional scanning galvanometer 103 is adjusted to set a specific wavelength and focal length, so that the focus point of the two beams of laser 104 is irradiated to the inner filling organic matter through the packaging shell of the chip 106, the motion trajectory of the two-dimensional motion platform 105 placing the defect chip 106 is adjusted, the platform is continuously moved, and the path of the laser 104 is modified to be graphene under the synergistic effect of the thermal effect and the photochemical synergistic effect in the process of laser 104 focusing. At this time, a three-dimensional path is scanned on the organic matter by the laser 104 focus point, the path is connected with two broken points of the internal circuit of the chip 106, and the graphene has electrical conductivity, so that the path can be a conductive circuit, so that the purpose of repairing the circuit break in the chip 106 is achieved.

The wavelength and frequency of the two beams of laser 104 are adjusted, so that two beams of the laser 104 produce stable interference and cancellation at the focus point.

When the two beams of laser 104 interfere and cancel at the focus point, a large amount of energy can be released, the wavelength and frequency of the laser 104 can be controlled, and stable interference and cancellation can be generated by the laser 104. The energy density of the focus point of the two beams of laser 104 is lower than the threshold value of denaturing of the filling material 202 before entering the filling organic matter and reaching the processing area, and the critical value is exceeded in the area where the processing is desired. The two beams of laser 104 generate pulses in a very short period of time, with the energy of its focal point being capable of instantaneously modifying the filling material 202 into graphene. Therefore, the incident laser 104 must have two beams, and interference and cancellation are generated between each other.

After the repair is completed, whether the repair is repaired or not is detected through the industrial CT detection, and whether the circuit pathways is intact or not is measured by means of electrical measurement. As to whether the filling material is modified into graphene, the sample can be sliced, and the Raman spectrum is used for measurement. Through the actual detection, the parameters of the laser are corrected according to the actual detection, so that the problem of circuit break repair is perfectly solved.

The speed range of the X and the Y axis of the two-dimensional motion platform in the S2 is 1-10 mm/s.

Since the size of the chip 106 is small, the distance of the broken path to be repaired will be shorter, so the speed of platform X and the Y axis of the two-dimensional motion platform 105 does not need to be too fast. However, due to the energy of the focusing point of the two beams of laser 104, the filling material 202 can be instantly modified into graphene, the speed of the platform X and the Y axis of the two-dimensional motion platform 105 cannot be too slow, so that the speed range of the X and the Y axis the two-dimensional motion platform 105 is 1-10 mm/s.

The wavelength range of the two beams of laser 104 is 300 nm˜1064 nm.

The difference of the injection molding material of the chip 106 results in a different degree of transparency, for the common epoxy resin, the light transmittance of the transparent material to the visible light of wavelength of 300 nm-1064 is more than 80%, and the light transmittance of the translucent material to the visible light of wavelength of 300 nm˜1064 nm is between 50%˜80%. In order to achieve a good modification effect, the wavelength range of the two beams of laser 104 adopted in the embodiment is 600˜800 nm.

An incident angle range of the two beams of laser is 0-90° from the vertical direction, and an included angle between the two beams of laser is 30-150°.

Because the focus point of the two beams of laser 104 needs to move inside the filling material 202 within the three-dimensional scale to form a conduction path, the incident angle range of the two beams of laser 104 is 0˜90° from the vertical direction, so that the focus point of the two beams of laser 104 can fall at any point in the three-dimensional space. At the same time, the energy density of the two beams of laser 104 after focusing in 0˜90° is large, and no loss is caused.

The value of the energy e of the focus point of the laser 104 needs to be greater than the modification threshold of the fill material 202 to achieve repair. The energy of the focus point of the laser 104 is

$$e = \frac{h c}{λ} \cdot \frac{π D}{4 {M}^{2} λ f} \cdot t$$

Wherein: h is the Planckian constant; c is the speed of light in the vacuum; λ is the wavelength of the laser 104; M² is the mode parameter of the laser 104, representing the divergence speed of a particular light beam in a propagation process, and the parameter is also provided in the specifications of the laser 103 manufacturer. f is the focal length of the three-dimensional galvanometer; D is the diameter of the input beam at the lens, t is the irradiation time of the laser 104 on the focus point. The incidence angle of the laser 104, the relationship between the included angle of the laser 104 and the refractive index of the material is:

$$\{ \begin{matrix}\frac{{L}_{1}}{tan {α}_{1}} + \frac{{L}_{2}}{tan {θ}_{1}} = {L}_{3} \\ \frac{{L}_{1}}{tan {α}_{2}} + \frac{{L}_{2}}{tan {θ}_{2}} = {L}_{4} \\ {L}_{3} + {L}_{4} = L \\ {θ}_{1} = \frac{sin {α}_{1}}{n} \\ {θ}_{2} = \frac{sin {α}_{2}}{n} \\ β = {α}_{1} + {α}_{2}\end{matrix}$$

Is the incident angle of one laser 104, is the incident angle of the other laser 104, and is the included angle of the two beams of laser 104;

α₁ is the incident angle of a beam of laser 104, θ₂ is a refraction angle of another beam of laser 104;

L₁ is the distance from the light source to the surface of the chip 106;

L₂ is the distance from the surface of the chip 106 to the focus point;

L is the distance between the two light sources;
n is the refractive index of the filler material 202.

When the included angle between the two beams of laser 104 is between 30˜150°, the two beams of laser 104 do not interfere with each other in position, and the energy of the focus point of the laser 104 can not be loss.

The focus point of the two beams of laser 104 in the S4 feeds through the two ends of the circuit break 204 of the chip 106 in a three-dimensional motion trajectory.

Since the focus point of the laser 104 is controllable, two broken points between lines can be connected in a three-dimensional curve according to actual needs, so that repairing the circuit break in the chip 106 is more flexible, and obstacles on the linear path can be avoided according to actual needs.

A repair device for repairing an internal circuit break defect in a chip 106 including: a computer system 101, a three-dimensional scanning galvanometer 102, a laser device 103 and a two-dimensional motion platform 105; the computer system 101 is respectively connected with the three-dimensional scanning galvanometer 103 and the two-dimensional motion platform 105; a defective chip 106 is placed on the two-dimensional motion platform 105; the three-dimensional scanning galvanometer 103 is arranged above the two-dimensional motion platform 105; and laser device 103 emits two beams of laser 104, and the two beams of laser 104 are focused on the circuit break position of the chip 106 through the three-dimensional scanning galvanometer 103.

Because the size of the chip 106 is small, the size of the internal circuit reaches a micron level, and the common laser 103 does not meet the precision requirement. The focal length of the Z axis of the three-dimensional scanning galvanometer 103 is adjustable, coordinating with the movement of the two-dimensional platform, so that a large accumulation error does not occur in the whole repairing process.

The laser device 103 has a power range of 150 W˜500 W, a wavelength range of 300 nm˜1064 nm, a scanning speed range of 0.5˜80 mm/s, an energy density range of 95-105 W/cm²; and a focal length of Z axis of the three-dimensional scanning galvanometer 103 has an adjustable range of 10˜150 mm.

The deformation threshold may be different for different fill materials 202. However, for common organic filler materials 202 such as epoxy, anhydride, acrylate and the like, the power range of the laser 103 is 150 W˜500 W, 300 nm˜1064 nm, and the scanning speed range is from 0.5 mm˜80 mm/s; when the energy density range is 95˜105 W/cm², the condition that the laser 104 induces graphene can be met. The adjustable range of the focal length of the Z-axis of the three-dimensional scanning galvanometer 103 ranges from 10 mm˜150 mm, and the focus point can be gathered at the circuit break 204 when the filling material 202 with different refractive indexes applied.

The above content is merely a preferred embodiment of the disclosure. For a person of ordinary skill in the art, according to the idea of the disclosure, changes can be made in the specific implementation manner and the application scope, the contents of the description shall not be construed as a limitation on the disclosure.

1. A method for repairing an internal circuit break defect in a chip, wherein the method comprising the following steps:
S1, performing industrial Computed Tomography (CT) detection on the chip, and detecting a defect position of the chip and type and performance parameters of an organic filling material in the chip, wherein the organic filling material is a material different from graphene;
S2, placing the chip on a two-dimensional motion platform, positioning the chip, calibrating an original point on the chip, and setting speed and displacement parameters of an X and Y axis of the two-dimensional motion platform;
S3, setting parameters of two beams of laser according to the performance parameters of the organic filling material, setting power, scanning speed and scanning frequency of the laser; adjusting a focal length of the two beams of laser three-dimensional incident angle and a Z axis, so that a focus point of the two beams of laser irradiate any end of the circuit break of the chip to modify the organic filling material at the end to be graphene;
S4, the two-dimensional motion platform drives the chip to move, so that the focus point of the two beams of laser is moved to an other end of the circuit break, and a moving trajectory of the focus point of the two beams of laser feeds through the two ends of the circuit break of the chip.

2. The method for repairing an internal circuit break defect in a chip according to claim 1, wherein adjusting a wavelength and frequency of the two beams of laser, so that the two beams of laser generate stable interference and cancellation at the focus points.

3. The method for repairing an internal circuit break defect in a chip according to claim 1, wherein a speed range of the X and the Y axis of the two-dimensional motion platform in the step S2 is 1-10 mm/s.

4. The method for repairing an internal circuit break defect in a chip according to claim 1, wherein a wavelength range of the two beams of laser is 300 nm to 1064 nm.

5. The method for repairing an internal circuit break defect in a chip according to claim 1, wherein an incident angle range of the two beams of laser is 0-90° from a vertical direction, and an included angle between the two beams of laser is 30-150°.

6. The method for repairing an internal circuit break defect in a chip according to claim 1, wherein the focus point of the two beams of laser in the step S4 feeds through the two ends of the circuit break of the chip in a three-dimensional motion trajectory.

7. A repair device using the method for repairing an internal circuit break defect in a chip according to claim 1, the repair device comprising: a computer system, a three-dimensional scanning galvanometer, a laser device and a two-dimensional motion platform; the computer system is respectively connected with the three-dimensional scanning galvanometer and the two-dimensional motion platform; a defective chip is placed on the two-dimensional motion platform; the three-dimensional scanning galvanometer is arranged above the two-dimensional motion platform; and laser device emits two beams of laser, and the two beams of laser are focused on the circuit break position of the chip through the three-dimensional scanning galvanometer.

8. A repair device using the method for repairing an internal circuit break defect in a chip according to claim 2, the repair device comprising: a computer system, a three-dimensional scanning galvanometer, a laser device and a two-dimensional motion platform; the computer system is respectively connected with the three-dimensional scanning galvanometer and the two-dimensional motion platform; a defective chip is placed on the two-dimensional motion platform; the three-dimensional scanning galvanometer is arranged above the two-dimensional motion platform; and laser device emits two beams of laser, and the two beams of laser are focused on the circuit break position of the chip through the three-dimensional scanning galvanometer.

9. A repair device using the method for repairing an internal circuit break defect in a chip according to claim 3, the repair device comprising: a computer system, a three-dimensional scanning galvanometer, a laser device and a two-dimensional motion platform; the computer system is respectively connected with the three-dimensional scanning galvanometer and the two-dimensional motion platform; a defective chip is placed on the two-dimensional motion platform; the three-dimensional scanning galvanometer is arranged above the two-dimensional motion platform; and laser device emits two beams of laser, and the two beams of laser are focused on the circuit break position of the chip through the three-dimensional scanning galvanometer.

10. A repair device using the method for repairing an internal circuit break defect in a chip according to claim 4, the repair device comprising: a computer system, a three-dimensional scanning galvanometer, a laser device and a two-dimensional motion platform; the computer system is respectively connected with the three-dimensional scanning galvanometer and the two-dimensional motion platform; a defective chip is placed on the two-dimensional motion platform; the three-dimensional scanning galvanometer is arranged above the two-dimensional motion platform; and laser device emits two beams of laser, and the two beams of laser are focused on the circuit break position of the chip through the three-dimensional scanning galvanometer.

11. A repair device using the method for repairing an internal circuit break defect in a chip according to claim 5, the repair device comprising: a computer system, a three-dimensional scanning galvanometer, a laser device and a two-dimensional motion platform; the computer system is respectively connected with the three-dimensional scanning galvanometer and the two-dimensional motion platform; a defective chip is placed on the two-dimensional motion platform; the three-dimensional scanning galvanometer is arranged above the two-dimensional motion platform; and laser device emits two beams of laser, and the two beams of laser are focused on the circuit break position of the chip through the three-dimensional scanning galvanometer.

12. A repair device using the method for repairing an internal circuit break defect in a chip according to claim 6, the repair device comprising: a computer system, a three-dimensional scanning galvanometer, a laser device and a two-dimensional motion platform; the computer system is respectively connected with the three-dimensional scanning galvanometer and the two-dimensional motion platform; a defective chip is placed on the two-dimensional motion platform; the three-dimensional scanning galvanometer is arranged above the two-dimensional motion platform; and laser device emits two beams of laser, and the two beams of laser are focused on the circuit break position of the chip through the three-dimensional scanning galvanometer.

13. The repairing device according to claim 7, wherein the laser device has a power range of 150 W˜500 W, a wavelength range of 300 nm˜1064 nm, a scanning speed range of 0.5˜80 mm/s, an energy density range of 95˜105 W/cm²; and a focal length of Z axis of the three-dimensional scanning galvanometer has an adjustable range of 10˜150 mm.

14. The repairing device according to claim 8, wherein the laser device has a power range of 150 W˜500 W, a wavelength range of 300 nm˜1064 nm, a scanning speed range of 0.5˜80 mm/s, an energy density range of 95-105 W/cm²; and a focal length of Z axis of the three-dimensional scanning galvanometer has an adjustable range of 10˜150 mm.

15. The repairing device according to claim 9, wherein the laser device has a power range of 150 W˜500 W, a wavelength range of 300 nm˜1064 nm, a scanning speed range of 0.5˜80 mm/s, an energy density range of 95-105 W/cm²; and a focal length of Z axis of the three-dimensional scanning galvanometer has an adjustable range of 10˜150 mm.

16. The repairing device according to claim 10, wherein the laser device has a power range of 150 W˜500 W, a wavelength range of 300 nm˜1064 nm, a scanning speed range of 0.5˜80 mm/s, an energy density range of 95-105 W/cm²; and a focal length of Z axis of the three-dimensional scanning galvanometer has an adjustable range of 10˜150 mm.

17. The repairing device according to claim 11, wherein the laser device has a power range of 150 W˜500 W, a wavelength range of 300 nm˜1064 nm, a scanning speed range of 0.5˜80 mm/s, an energy density range of 95-105 W/cm²; and a focal length of Z axis of the three-dimensional scanning galvanometer has an adjustable range of 10˜150 mm.

18. The repairing device according to claim 12, wherein the laser device has a power range of 150 W˜500 W, a wavelength range of 300 nm˜1064 nm, a scanning speed range of 0.5˜80 mm/s, an energy density range of 95-105 W/cm²; and a focal length of Z axis of the three-dimensional scanning galvanometer has an adjustable range of 10˜150 mm.
